(19) United States
(12) Patent Application Publication
(10) Pub. No.: US 2015/0137081 A1
(43) Pub. Date: May 21, 2015

(54) ORGANIC LIGHT-EMITTING DISPLAY APPARATUS

(71) Applicant: Samsung Display Co., Ltd., Yongin-city (KR)

(72) Inventors: Jae-Kyoung Kim, Yongin-city (KR); Gee-Bum Kim, Yongin-city (KR); Won-Sang Park, Yongin-city (KR)

(73) Assignee: Samsung Display Co., Ltd., Yongin-city (KR)

(21) Appl. No.: 14/208,377

(22) Filed: Mar. 13, 2014

(30) Foreign Application Priority Data
Nov. 15, 2013 (KR) 10-2013-0139325

(51) Int. Cl. H01L 27/32; H01L 51/52

(52) U.S. Cl. CPC H01L 27/3211; H01L 51/5275; H01L 51/5271; H01L 51/5234; H01L 51/5218
USPC 257/40

(57) ABSTRACT

An organic light-emitting display apparatus, including a substrate including a first subpixel region, a second subpixel region, and a third subpixel region, a first pixel electrode, a second pixel electrode, and a third pixel electrode disposed respectively in the first subpixel region, the second subpixel region, and the third subpixel region, a first intermediate layer, a second intermediate layer, and a third intermediate layer disposed respectively on the first pixel electrode, the second pixel electrode, and the third pixel electrode and including an organic emission layer, an opposite electrode disposed on the first intermediate layer, the second intermediate layer, and the third intermediate layer, and a dielectric reflective layer including at least one pair of high refractive layers and low refractive layers stacked alternately and disposed between the substrate, and the first pixel electrode and the second pixel electrode, wherein the third pixel electrode includes a metal layer.

### CROSS-REFERENCE TO RELATED APPLICATIONS

This application claims priority from and the benefit of Korean Patent Application No. 10-2013-0139325, filed on Nov. 15, 2013, which is hereby incorporated by reference for all purposes as if fully set forth herein.

### BACKGROUND

1. Field

Exemplary embodiments of the present invention relate to organic light-emitting display apparatuses.

2. Discussion of the Background

In general, an organic light-emitting display apparatus is a self-luminous display apparatus that includes a plurality of organic light-emitting devices each including a hole injection electrode, an electron injection electrode, and an organic emission layer formed therebetween. Excitons are generated when holes injected from the hole injection electrode and electrons injected from the electron injection electrode are combined in the organic emission layer, and light is generated when the excitons drop from an excited state to a ground state.

Since the organic light-emitting display apparatus, which is a self-luminous display apparatus, does not use a separate light source, it may be driven by a low voltage and may be lightweight and slim. Also, since the organic light-emitting display apparatus is excellent in terms of a viewing angle, a contrast, and a response time, it is widely used in personal portable devices, such as MP3 players and mobile phones, and televisions (TVs).

The above information disclosed in this Background section is only for enhancement of understanding of the background of the invention and therefore it may contain information that does not form any part of the prior art nor what the prior art may suggest to a person of ordinary skill in the art.

### SUMMARY

Exemplary embodiments of the present invention provide organic light-emitting display apparatuses.

Additional features of the invention will be set forth in the description which follows, and in part will be apparent from the description, or may be learned by practice of the presented embodiments.

An exemplary embodiment of the present invention discloses an organic light-emitting display apparatus, including a substrate including a first subpixel region, a second subpixel region, and a third subpixel region, a first pixel electrode, a second pixel electrode, and a third pixel electrode disposed respectively in the first subpixel region, the second subpixel region, and the third subpixel region, a first intermediate layer, a second intermediate layer, and a third intermediate layer disposed respectively on the first pixel electrode, the second pixel electrode, and the third pixel electrode and including an organic emission layer, an opposite electrode disposed on the first intermediate layer, the second intermediate layer, and the third intermediate layer, and a dielectric reflective layer including at least one pair of a first refractive layer and a second refractive layer stacked alternately and disposed between the substrate and the first pixel electrode and between the substrate and the second pixel electrode, wherein the first refractive layer has higher refractive index than the second refractive layer, and the third pixel electrode includes a metal layer.

An exemplary embodiment of the present invention also discloses an organic light-emitting display apparatus, including a substrate including a first subpixel region, a second subpixel region, and a third subpixel region, a first pixel electrode, a second pixel electrode, and a third pixel electrode disposed respectively in the first subpixel region, the second subpixel region, and the third subpixel region, a first intermediate layer, a second intermediate layer, and a third intermediate layer disposed respectively on the first pixel electrode, the second pixel electrode, and the third pixel electrode and including an organic emission layer, an opposite electrode disposed on the first intermediate layer, the second intermediate layer, and the third intermediate layer, a first dielectric reflective layer including at least one pair of a first refractive layer and a second refractive layer stacked alternately and disposed between the substrate and the first pixel electrode, and a second dielectric reflective layer including at least one pair of a first refractive layer and a second refractive layer stacked alternately and disposed between the substrate and the second pixel electrode, wherein the first refractive layer has higher refractive index than the second refractive layer, and the third pixel electrode includes a metal layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a schematic cross-sectional view illustrating an organic light-emitting display apparatus according to an exemplary embodiment of the present invention.

FIGS. 2A, 2B, and 2C are schematic cross-sectional views illustrating a first subpixel region, a second subpixel region, and a third subpixel region of FIG. 1.

FIG. 3 is a graph illustrating a color shift depending on side viewing angles of the organic light-emitting display apparatus according to the exemplary embodiment of FIG. 1 and a color shift depending on side viewing angles of an organic light-emitting display apparatus according to a comparative example of FIG. 9;

FIGS. 4A, 4B, and 4C are graphs illustrating color coordinates depending on the side viewing angles of the organic light-emitting display apparatus according to the exemplary embodiment of FIG. 1.

FIGS. 5A, 5B, and 5C are graphs illustrating color coordinates depending on the side viewing angles of the organic light-emitting display apparatus according to the comparative example of FIG. 9.

FIG. 6 is a graph illustrating a luminance ratio depending on the side viewing angles of the organic light-emitting display apparatus according to the exemplary embodiment of FIG. 1.

FIG. 7 is a graph illustrating a color shift depending on a thickness change of a high refractive layer and a low refractive layer included in the organic light-emitting display apparatus according to the exemplary embodiment of FIG. 1.

FIG. 8 is a schematic cross-sectional view illustrating an organic light-emitting display apparatus according to another exemplary embodiment of the present invention.

FIG. 9 is a schematic cross-sectional view illustrating an organic light-emitting display apparatus according to the comparative example.

### DETAILED DESCRIPTION OF THE ILLUSTRATED EMBODIMENTS

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, expressions such as “at least one of,” when preceding a list of elements, modify the entire list of elements and do not modify the individual elements of the list.

The present invention may include various embodiments and modifications, and exemplary embodiments thereof are illustrated in the drawings and will be described herein in detail. The effects and features of the present invention and the accomplishing methods thereof will become apparent from the following description of the embodiments, taken in conjunction with the accompanying drawings. However, the prevent invention is not limited to the embodiments described below, and may be embodied in various modes.

Hereinafter, embodiments of the present invention will be described in detail with reference to the accompanying drawings. In the following description, like reference numerals denote like elements, and a redundant description thereof will be omitted.

It will be understood that although the terms “first”, “second”, etc. may be used herein to describe various components, these components should not be limited by these terms. These terms are only used to distinguish one component from another.

As used herein, the singular forms “a”, “an”, and “the” are intended to include the plural forms as well, unless the context clearly indicates otherwise.

It will be further understood that the terms “comprise”, “include”, and “have” used herein specify the presence of stated features or components, but do not preclude the presence or addition of one or more other features or components.

It will be understood that when a layer, region, or component is referred to as being “formed on” another layer, region, or component, it may be directly or indirectly formed on the other layer, region, or component. That is, for example, intervening layers, regions, or components may be present. In contrast, when an element or layer is referred to as being “directly on” or “directly connected to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

Sizes of components in the drawings may be exaggerated for convenience of description. In other words, since sizes and thicknesses of components in the drawings are arbitrarily illustrated for convenience of description, the following embodiments are not limited thereto.

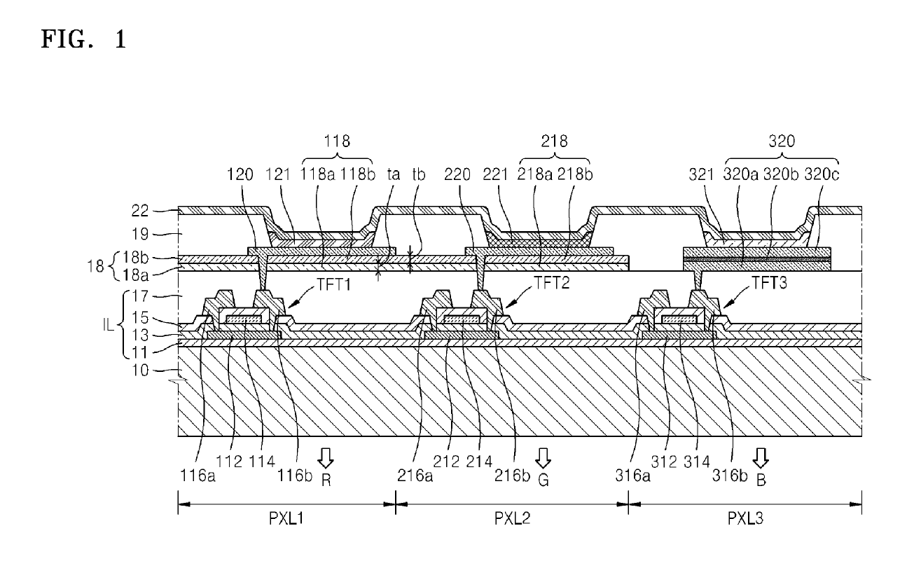

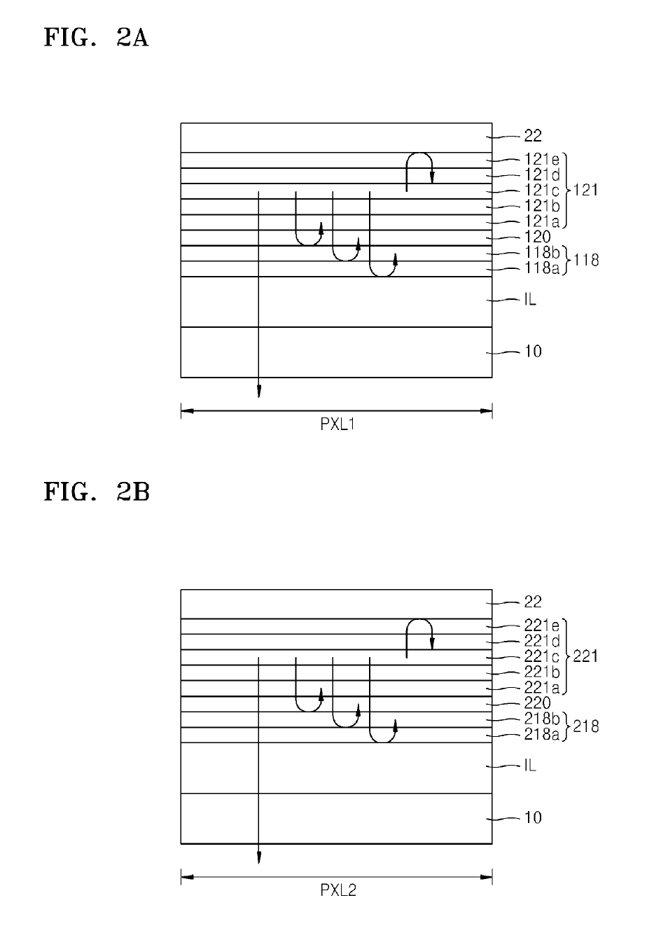

FIG. 1 is a schematic cross-sectional view illustrating an organic light-emitting display apparatus according to an exemplary embodiment of the present invention. FIGS. 2A, 2B, and 2C are schematic cross-sectional views illustrating a first subpixel region, a second subpixel region, and a third subpixel region of FIG. 1.

Referring to FIG. 1, an organic light-emitting display apparatus according to an exemplary embodiment of the present invention includes a substrate 10 that is divided into a first subpixel region PXL1, a second subpixel region PXL2, and a third subpixel region PXL3. The first subpixel region PXL1 includes a first pixel electrode 120, a first intermediate layer 121, and an opposite electrode 22 that are sequentially disposed on the substrate 10, and the first intermediate layer 121 includes a first organic emission layer.

A first dielectric reflective layer 118 including a high refractive layer 118a and a low refractive layer 118b may be disposed between the substrate 10 and the first pixel electrode 120.

The second subpixel region PXL2 includes a second pixel electrode 220, a second intermediate layer 221, and an opposite electrode 22 that are sequentially disposed on the substrate 10, and the second intermediate layer 221 includes a second organic emission layer.

A second dielectric reflective layer 218 including a high refractive layer 218a and a low refractive layer 218b may be disposed between the substrate 10 and the second pixel electrode 220.

The third subpixel region PXL3 includes a third pixel electrode 320, a third intermediate layer 321, and an opposite electrode 22 that are sequentially disposed on the substrate 10, and the third intermediate layer 321 includes a third organic emission layer.

The third pixel electrode 320 may include a semitransparent metal layer 320b, a first transparent conductive layer 320a, and a second transparent conductive layer 320b. The first transparent conductive layer 320a and the second transparent conductive layer 320c may be disposed respectively under and on the semitransparent metal layer 320b to protect the semitransparent metal layer 320b.

End portions of the first pixel electrode 120, the second pixel electrode 220, and the third pixel electrode 320 may be covered by a pixel definition layer 19.

Referring to FIGS. 2A and 2B, the first pixel electrode 120 and the second pixel electrode 220 are disposed respectively on the first subpixel region PXL1 and the second subpixel region PXL2 of the substrate 10 including a transparent substrate formed of glass or plastics. The first pixel electrode 120 and the second pixel electrode 220 may include transparent conductive oxide, for example, selected from at least one of the group consisting of indium tin oxide (ITO), indium zinc oxide (IZO), zinc oxide (ZnO), indium oxide (In₂O₃), indium gallium oxide (IGO), and aluminum zinc oxide (AZO).

The first intermediate layer 121 and the second intermediate layer 221 are disposed respectively on the first pixel electrode 120 and the second pixel electrode 220. The first/second intermediate layer 121/221 may include a first/second organic emission layer 121c/221c and may further include at least one of a hole injection layer (HIL) 121a/221a, a hole transport layer (HTL) 121b/221b, an electron transport layer (ETL) 121d/221d, and an electron injection layer (EIL) 121e/221e, respectively. However, embodiments of the present invention are not limited thereto, and the first/second intermediate layer 121/221 may further include various other functional layers.

The opposite electrode 22 is disposed on the first intermediate layer 121 and the second intermediate layer 221. The opposite electrode 22 may include a reflective metal electrode, selected from at least one of the group consisting of silver (Ag), aluminum (Al), magnesium (Mg), lithium (Li), calcium (Ca), copper (Cu), LiF/Ca, LiF/Al, MgAg, and CaAg.

The first/second organic emission layer 121c/221c may respectively emit a red/green light, and the red/green light emitted toward the opposite electrode 22 may be reflected by the opposite electrode 22 and then emitted through the first/second pixel electrode 120/220 to the substrate 10.

That is, the organic light-emitting display apparatus according to the present embodiment may be a bottom emission type display apparatus that emits light to the substrate 10.

Referring back to FIG. 1, a dielectric reflective layer 18 including at least one pair of high refractive layers 18a and low refractive layers 18b disposed alternately may be disposed between the substrate 10 and the first/second pixel electrode 120/220, and the dielectric reflective layer 18 may include the first dielectric reflective layer 118 corresponding to the first pixel electrode 120 and the second dielectric reflective layer 218 corresponding to the second pixel electrode 220.

The dielectric reflective layer 18 may function as a distributed Bragg reflector (DBR), a reflective structure in which high refractive layers and low refractive layers are alternately disposed to reflect a specific wavelength of light such that lights reflected from the interfaces between the high refractive layers and the low refractive layers satisfy a constructive interference condition.

The path of light emitted from the first organic emission layer 121c included in the first subpixel region PXL1 is described below in detail. Light emitted from the first organic emission layer 121c travels in all directions. Light emitted from the first organic emission layer 121c that travels toward the opposite electrode 22 may be reflected by the opposite electrode 22 toward the first pixel electrode 120.

A portion of light emitted from the first organic emission layer 121c or reflected by the opposite electrode 22 toward the first pixel electrode 120 may travel toward the substrate 10 and be emitted to the outside, and other portions of the light may be reflected at the interface between the first pixel electrode 120 and the low refractive layer 118b, the interface between the low refractive layer 118b and the high refractive layer 118a, and the interface between the high refractive layer 118a and an insulating layer IL disposed between the substrate 10 and the high refractive layer 118a.

That is, a weak cavity structure may be formed by the first dielectric reflective layer 118, and the luminescent efficiency and the color purity of light (e.g., red light) emitted from the first subpixel region PXL1 may be improved.

Light emitted from the second organic emission layer 221c included in the second subpixel region PXL2 may be emitted to the outside through the same path as the light emitted from the first organic emission layer 121c included in the first subpixel region PXL1.

A portion of the light emitted from the second organic emission layer 221c may be reflected at the interface between the second pixel electrode 220 and the low refractive layer 218b, the interface between the low refractive layer 218b and the high refractive layer 218a, and the interface between the high refractive layer 218a and an insulating layer IL disposed between the substrate 10 and the high refractive layer 218a.

That is, a weak cavity structure may be formed by the second dielectric reflective layer 218, and the luminescent efficiency and the color purity of light (e.g., green light) emitted from the second subpixel region PXL2 may be improved.

Referring to FIG. 2C, the third pixel electrode 320 is disposed on the third subpixel region PXL3 of the substrate 10. The third pixel electrode 320 may include the semitransparent metal layer 320b and the first and second transparent conductive layers 320a and 320c disposed to protect the semitransparent metal layer 320b.

The first and second transparent conductive layers 320a and 320c may include at least one selected from the group consisting of ITO, IZO, ZnO, In₂O₃, IGO, and AZO. The semitransparent metal layer 320b may include Ag and Ag alloy having a thickness of about 100 Å to about 200 Å.

The third intermediate layer 321 is disposed on the third pixel electrode 320. The third intermediate layer 321 may include a third organic emission layer 321c and may further include at least one of an HIL 321a, an HTL 321b, an ETL 321d, and an EIL 321e. However, the present embodiment is not limited thereto, and the third intermediate layer 321 may further include various other functional layers.

The opposite electrode 22 is disposed on the third intermediate layer 321. The opposite electrode 22 may include a reflective metal layer, and may be disposed in common in the first subpixel region PXL1, the second subpixel region PXL2, and the third subpixel region PXL3.

A path of light emitted from the third subpixel region PXL3 is described below in detail. Light emitted from the third organic emission layer 321c travels in all directions. Light emitted from the third organic emission layer 321c that travels toward the opposite electrode 22 may be reflected by the opposite electrode 22 toward the first pixel electrode 120.

A portion of light emitted from the third organic emission layer 321 or reflected by the opposite electrode 22 toward the third pixel electrode 320 may be reflected by the semitransparent metal layer 320b toward the opposite electrode 22, and other portion of the light may travel toward the substrate 10 and be emitted to the outside.

That is, a portion of the light emitted from the third organic emission layer 321c reciprocates between the third pixel electrode 320 and the opposite electrode 22, and only light of a wavelength satisfying a constructive interference condition may be amplified and emitted toward the substrate 10.

That is, a microcavity structure may be formed by the semitransparent metal layer 320b of the third pixel electrode 320 and the opposite electrode 22, and thus, the luminescent efficiency and the color purity of light (e.g., blue light) emitted from the third subpixel region PXL3 may be improved.

The third intermediate layer 321 included in the third subpixel region PXL3 may include a cavity distance control layer configured to control the distance between the first pixel electrode 120 and the opposite electrode 22, and the HTL 121b may function as the cavity distance control layer.

The third organic emission layer 321c emits light with a relatively wide wavelength range, and only a portion of the light, which satisfies a resonance condition (i.e., a constructive interference condition) of the microcavity structure, is amplified and emitted to the outside.

In this case, a wavelength of the light emitted to the outside is determined according to the distance between the semitransparent metal layer 320b and the opposite electrode 22. Thus, by controlling the distance between the semitransparent metal layer 320b and the opposite electrode 22, a desired wavelength of light may be emitted to the outside.

The third subpixel region PXL3 of the present embodiment may emit blue light. The microcavity structure included in the third subpixel region PXL3 may be configured to emit blue light with certain wavelength value.

Referring back to FIG. 1, the organic light-emitting display apparatus of the present embodiment may include a first thin film transistor TFT1, a second thin film transistor TFT2, and a third thin film transistor TFT3 that are electrically connected respectively to the first pixel electrode 120, the second pixel electrode 220, and the third pixel electrode 320.

A buffer layer 11 may be disposed on the substrate 10, and active layers 112, 212 and 312 of the first to third thin film transistors TFT1, TFT2 and TFT3 may be respectively disposed on the buffer layer 11. The buffer layer 11 may planarize the surface of the substrate 10 and may prevent impurities from infiltrating into the active layers 112, 212 and 312.

The active layers 112, 212, and 312 may include various materials. For example, the active layers 112, 212, and 312 may include at least one of an inorganic semiconductor material such as amorphous silicon or crystalline silicon, an oxide semiconductor, and an organic semiconductor material.

A gate insulating layer 13 may be disposed on the buffer layer 11 to cover the active layers 112, 212, and 312. Gate electrodes 114, 214, and 314 may be disposed on the gate insulating layer 13.

The gate electrodes 114, 214, and 314 may be formed to have a single-layer structure or a multilayer structure including at least one of aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and copper (Cu).

An interlayer insulating layer 15 may be disposed on the gate electrodes 114, 214, and 314. Source electrodes 116a, 216a, and 316a and drain electrodes 116b, 216b, and 316b may be disposed on the interlayer insulating layer 15.

The source electrodes 116a, 216a, and 316a and the drain electrodes 116b, 216b, and 316b may be formed to have a single-layer structure or a multilayer structure including at least one of Al, Pt, Pd, Ag, Mg, Au, Ni, Nd, Ir, Cr, Li, Ca, Mo, Ti, W, and Cu.

A planarization layer 17 may be formed on the first to third thin film transistors TFT1, TFT2, and TFT3 to cover the first to third thin film transistors TFT1, TFT2, and TFT3. The planarization film 17 may include an acryl-based organic material or benzocyclobutene (BCB).

The dielectric reflective layer 18 including the high refractive layers 18a and the low refractive layers 18b may be disposed between the planarization layer 17 and the first/second pixel electrode 120/220, the low refractive layers 18b contacting the first pixel electrode 120 and the second pixel electrode 220.

The first pixel electrode 120 and the second pixel electrode 220 may include transparent conductive oxide, for example, ITO having a high refractive index of about 1.7 or more. Therefore, by disposing the low refractive layer 18b under the first pixel electrode 120 and the second pixel electrode 220, the reflectance at the interfaces between the first/second pixel electrode 120/220 and the low refractive layers 18b may be increased increasing a resonance effect.

Likewise, since the planarization layer 17 including an organic material has a low refractive index, the high refractive layers 18a may be disposed contacting the planarization layer 17.

The low refractive layer 18b may include silica (SiO₂), and the high refractive layer 18a may include silicon nitride (SiNₓ); however, embodiments of the present invention are not limited thereto.

Although FIG. 1 illustrates a configuration in which only one pair of high refractive layer 18a and low refractive layer 18b are disposed, embodiments of the present invention are not limited thereto. For example, a plurality of high refractive layers and low refractive layers may be disposed under the first pixel electrode 120 and the second pixel electrode 220, and the number of high refractive layers may be different from the number of low refractive layers.

Also, although present exemplary embodiment specifies red, green, and blue sub-pixels, present invention is not limited thereto, and may include other colors, such as cyan, magenta, and yellow.

The dielectric reflective layer 18 may include the first dielectric reflective layer 118 disposed to correspond to the first pixel electrode 120 and the second dielectric reflective layer 218 disposed to correspond to the second pixel electrode 220, and the first dielectric reflective layer 118 and the second dielectric reflective layer 218 may be integrally formed.

That is, a region extending from the first dielectric reflective layer 118 to the second subpixel region PXL2 may correspond to the second dielectric reflective layer 218.

Therefore, the first dielectric reflective layer 118 and the second dielectric reflective layer 218 may have the same thickness, and a thickness to of the high refractive layer 118a and a thickness tb of the low refractive layer 118b, may be about 760 Å to about 840 Å.

By the above configuration of the dielectric reflective layer 18, the first dielectric reflective layer 118 and the second dielectric reflective layer 218 may be simultaneously formed through one deposition and etching process, and red light and green light may be simultaneously adjusted to standard values for implementing white light.

Since the weak cavity structure is introduced in the first subpixel region PXL1 and the second subpixel region PXL2 and the microcavity structure is introduced in the third subpixel region PXL3, the organic light-emitting display apparatus of the embodiment of FIG. 1 may prevent a color shift at side viewing angles, which may be caused when the microcavity structure is introduced in all of the subpixel regions in order to improve luminescent efficiency.

Also, since the microcavity structure is introduced in the third subpixel region PXL3 emitting blue light, the blue light may be adjusted to a standard value (s-RGB).

TABLE 1

| | | |
|---|---|---|
| Blue | Green | Red |

| Front Color | x | y | x | y | x | y |
|---|---|---|---|---|---|---|
| Embodiment | 0.139 | 0.051 | 0.213 | 0.704 | 0.668 | 0.329 |
| of FIG. 1 | | | | | | |
| s-RGB | 0.150 | 0.060 | 0.300 | 0.600 | 0.640 | 0.330 |

Table 1 illustrates color coordinate values of lights emitted from the first subpixel region PXL1, the second subpixel region PXL2, and the third subpixel region PXL3 of the organic light-emitting display apparatus of FIG. 1. Referring to Table 1, the color coordinate values of red light, green light, and blue light emitted from the organic light-emitting display apparatus of FIG. 1 are substantially similar to that of standard RGB (s-RGB) within a predetermined error range. In particular, the color coordinate value of the blue light is almost identical to the color coordinate value of the standard RGB from introducing the microcavity structure in the blue subpixel region, in which wavelength value is difficult to adjust using the weak cavity structure.

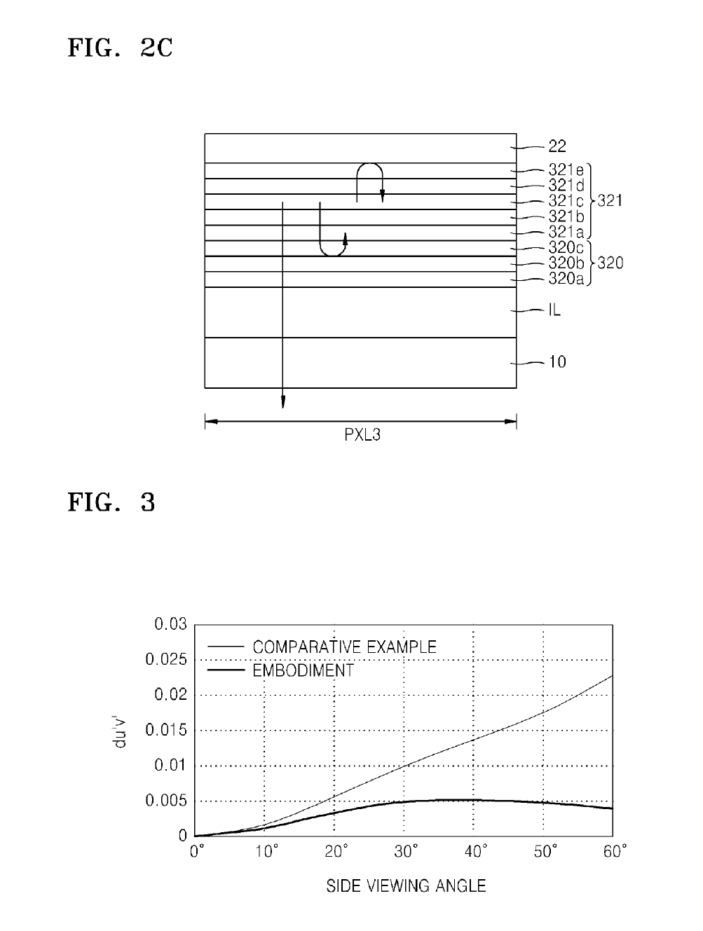

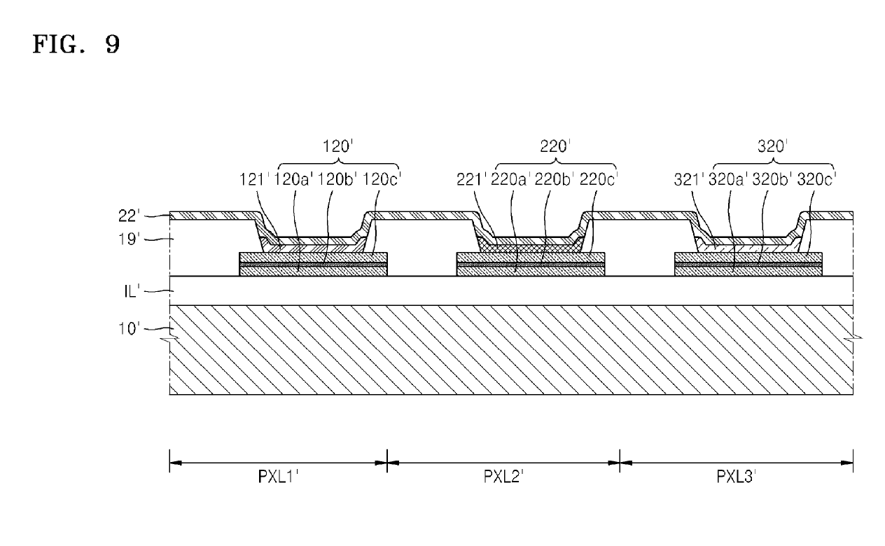

FIG. 3 is a graph illustrating a color shift depending on side viewing angles of the organic light-emitting display apparatus according to the embodiment of FIG. 1 and a color shift depending on side viewing angles of an organic light-emitting display apparatus according to a comparative example of FIG. 9. FIG. 9 is a schematic cross-sectional view illustrating an organic light-emitting display apparatus according to a comparative example.

Referring to FIG. 9, the organic light-emitting display apparatus according to the comparative example includes a substrate 10′ that is divided into a first subpixel region PXL1′, a second subpixel region PXL2′, and a third subpixel region PXL3′.

A first pixel electrode 120′, a second pixel electrode 220′, and a third pixel electrode 320′, which are included respectively in the first subpixel region PXL1′, the second subpixel region PXL2′, and the third subpixel region PXL3′, respectively include a first semitransparent metal layer 120b′, a second semitransparent metal layer 220b′, and a third semitransparent metal layer 320b; and an opposite electrode 22′ includes a reflective metal layer.

The first pixel electrode 120′, the second pixel electrode 220′, and the third pixel electrode 320′ may further include transparent conductive layers 120a′ and 120c′, 220a′ and 220c′, and 320a′ and 320c′ protecting the first semitransparent metal layer 120b′, the second semitransparent metal layer 220b′, and the third semitransparent metal layer 320b′, respectively. End portions of the first pixel electrode 120′, the second pixel electrode 220′, and the third pixel electrode 320′ may be covered by a pixel definition layer 19′.

An insulating layer IL′ such as a buffer layer may be disposed on the substrate 10; and a first intermediate layer 121′, a second intermediate layer 221′, and a third intermediate layer 321′, which emit red light, green light, and blue light, are disposed respectively on the first pixel electrode 120′, the second pixel electrode 220′, and the third pixel electrode 320′.

In other words, all the first subpixel region PLX1′, the second subpixel region PXL2′, and the third subpixel region PXL3′ include a microcavity structure.

A horizontal axis of the graph of FIG. 3 represents a side viewing angle of an organic light-emitting display apparatus, and a vertical axis represents a color coordinate value change (i.e., a color shift) of white light implemented by a combination of red light, green light, and blue light with respect to the normal direction)(0° of the organic light-emitting display apparatus.

Referring to the graph of FIG. 3, the color shift at the side viewing angle of the organic light-emitting display apparatus according to the embodiment of FIG. 1 is significantly less than that of the organic light-emitting display apparatus according to the comparative example of FIG. 9.

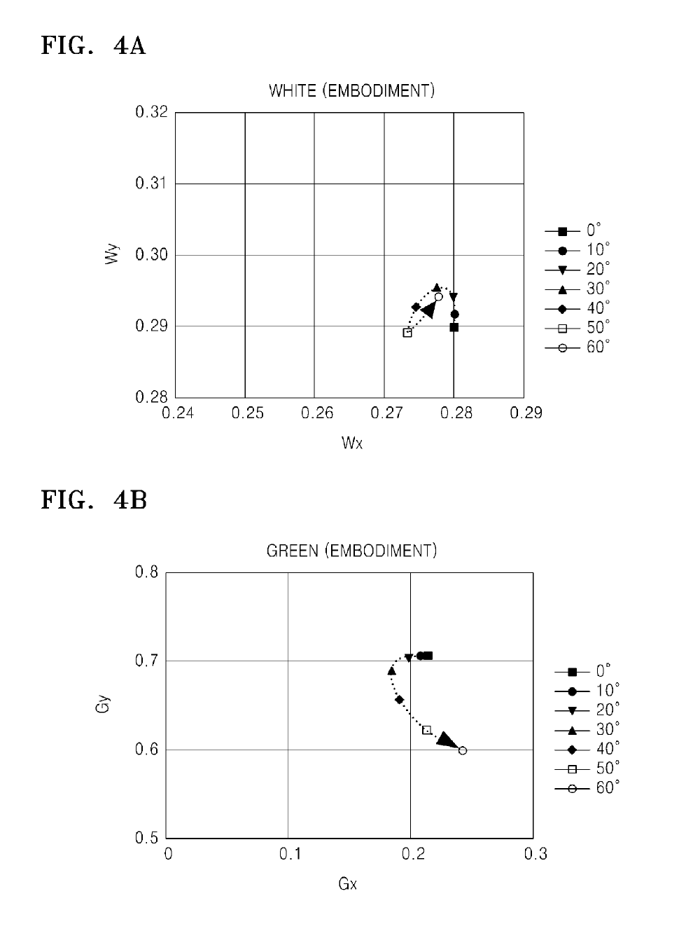

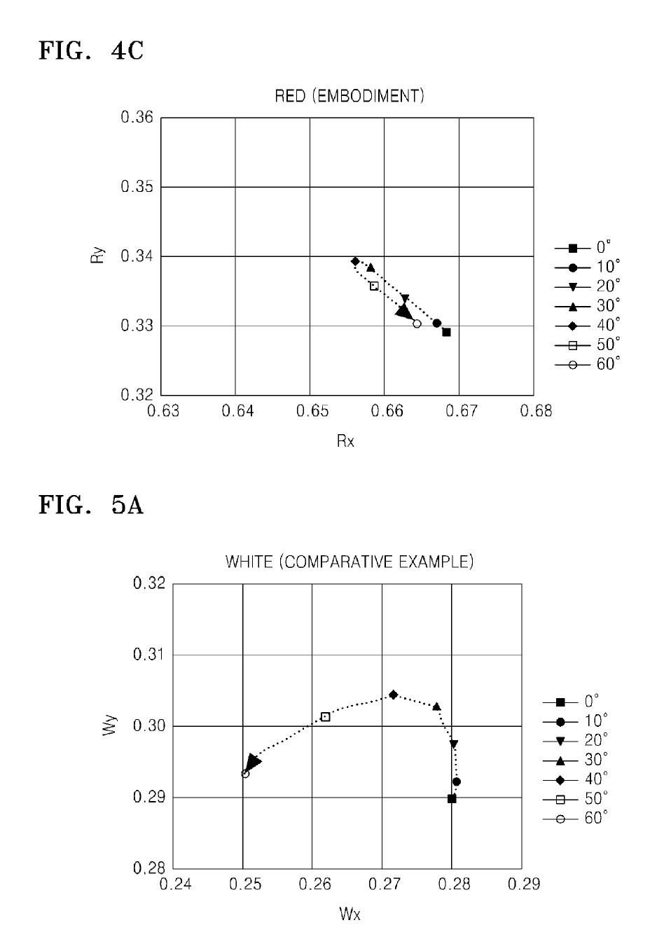

FIGS. 4A, 4B, and 4C are graphs illustrating color coordinates depending on the side viewing angles of the organic light-emitting display apparatus according to the embodiment of FIG. 1. FIGS. 5A, 5B, and 5C are graphs illustrating color coordinates depending on the side viewing angles of the organic light-emitting display apparatus according to the comparative example of FIG. 9.

FIGS. 4A, 4B, and 4C respectively illustrate color coordinate values of white light, green light, and red light emitted from the organic light-emitting display apparatus according to the embodiment of FIG. 1, observed from the x-axis (the horizontal direction of the organic light-emitting display apparatus) and the y-axis (the vertical direction of the organic light-emitting display apparatus). FIGS. 5A, 5B, and 5C respectively illustrate color coordinate values of white light, green light, and red light emitted from the organic light-emitting display apparatus according to the comparative example of FIG. 9, observed from the x-axis and the y-axis.

Comparing FIGS. 4A, 4B, and 4C to FIGS. 5A, 5B, and 5C, respectively, the color coordinate value changes depending on the side viewing angles in the organic light-emitting display apparatus according to the embodiment of FIG. 1 are much smaller than the color coordinate value change depending on the side viewing angles in the organic light-emitting display apparatus according to the comparative example of FIG. 9.

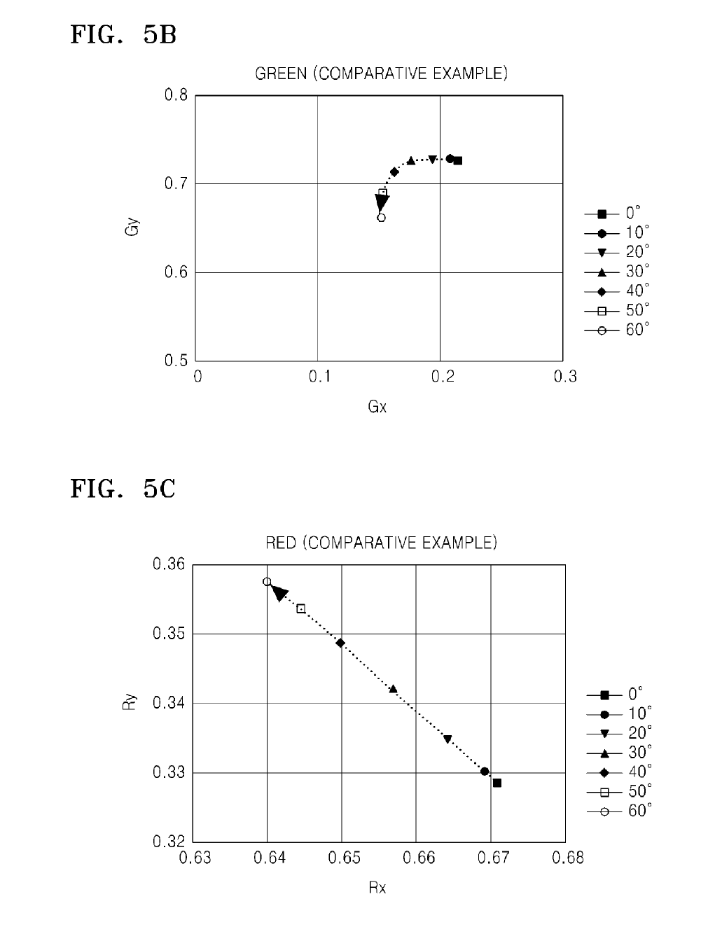

FIG. 6 is a graph illustrating a luminance ratio depending on the side viewing angles of the organic light-emitting display apparatus according to the exemplary embodiment of FIG. 1.

Referring to FIG. 6, the luminance values of red light RED, green light GREEN, and blue light BLUE decrease at substantially the same rate as the side viewing angle increases.

In other words, a color shift caused by the luminance discrepancy between the red light, the green light, and the blue light at the side viewing angle can be reduced in the organic light-emitting display apparatus according to the embodiment of FIG. 1, since the luminance values of the red light, the green light, and the blue light are substantially equal at a specific side viewing angle.

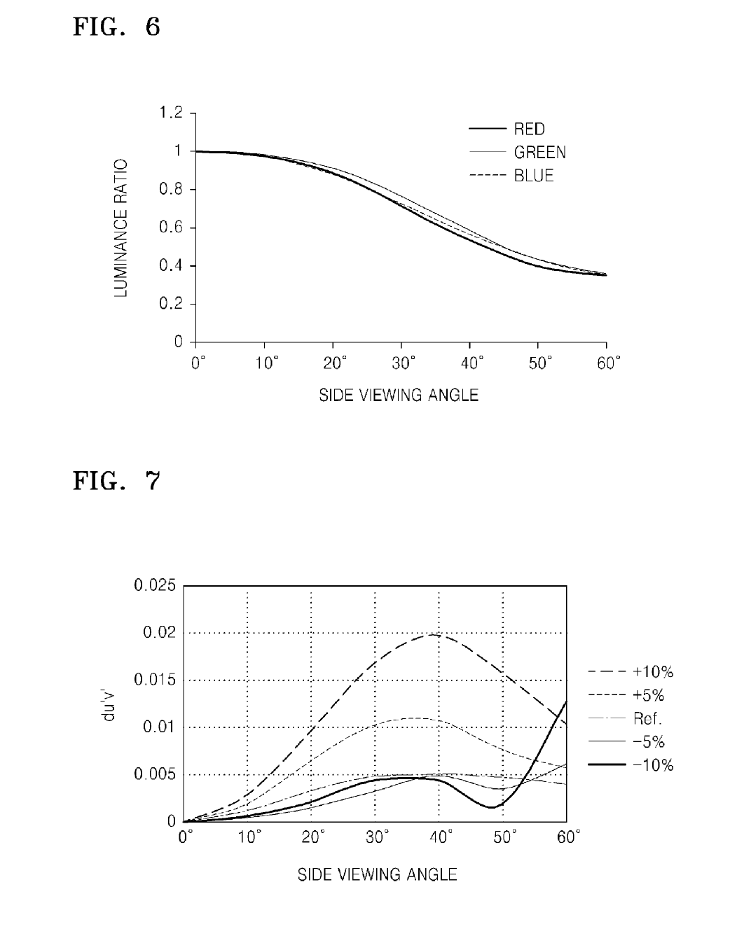

FIG. 7 is a graph illustrating a color shift depending on a thickness change of the high refractive layer 18a and the low refractive layer 18b included in the organic light-emitting display apparatus according to the exemplary embodiment of FIG. 1.

The graph of FIG. 7 illustrates the degree of a color shift depending on side viewing angles, when the thickness ta of the high refractive layer 18a of FIG. 1 and the thickness tb of the low refractive layer 18b of FIG. 1 change respectively by about ±5% and about ±10% with respect to a reference value Ref, 800 Å.

This thickness change may represent error in the process of forming the high refractive layer 18a and the low refractive layer 18b.

Referring to the graph of FIG. 7, when the thickness change is about ±5%, which means that the thickness ta of the high refractive layer 18a and the thickness tb of the low refractive layer 18b are about 760 Å and about 840 Å, a color coordinate value change at a side viewing angle of about 60° has a value of about 0.006. When the thickness change is about ±10%, which means the thickness ta of the high refractive layer 18a and the thickness tb of the low refractive layer 18b are about 720 Å and about 880 Å, a color coordinate value change at a side viewing angle of about 60° has a value of about 0.01 or more.

Therefore, in order to implement an organic light-emitting display apparatus having a color coordinate value change of about 0.01 or less, the thickness of the high refractive layer 18a and the thickness of the low refractive layer 18b may be set to have a value ranging from about 760 Å to about 840 Å.

Table 2 illustrates the x and y coordinate values depending on a change in the thicknesses ta and tb of the high refractive layer 18a and the low refractive layer 18b of the embodiment of FIG. 1, and color shift values at a position corresponding to a side viewing angle of about 60°.

TABLE 2

| Front | Blue | | Green | | Red | | Color Shift |
|---|---|---|---|---|---|---|---|
| Color | x | y | x | y | x | y | (@60°) |
| +10% | 0.139 | 0.051 | 0.250 | 0.688 | 0.676 | 0.320 | 0.010 |
| +5% | 0.139 | 0.051 | 0.230 | 0.699 | 0.672 | 0.325 | 0.006 |
| REF. | 0.139 | 0.051 | 0.213 | 0.704 | 0.668 | 0.329 | 0.004 |
| −5% | 0.139 | 0.051 | 0.201 | 0.703 | 0.664 | 0.332 | 0.006 |
| −10% | 0.139 | 0.051 | 0.194 | 0.695 | 0.661 | 0.335 | 0.013 |

Referring to Table 2, when the thicknesses ta and tb of the high refractive layer 18a and the low refractive layer 18b included in the embodiment of FIG. 1 are changed, the color coordinate value of the blue light shows no changed because the third subpixel region PXL3 does not include the low refractive layer and the high refractive layer, but the color coordinate values of the green light and the red light are changed with respect to the reference value.

Referring back to the graph of FIG. 7, the color shifts at a side viewing angle of about 60° in the rightmost column of Table 2 show that low color shift value of about 0.006 may be provided when the thickness change is about ±5%.

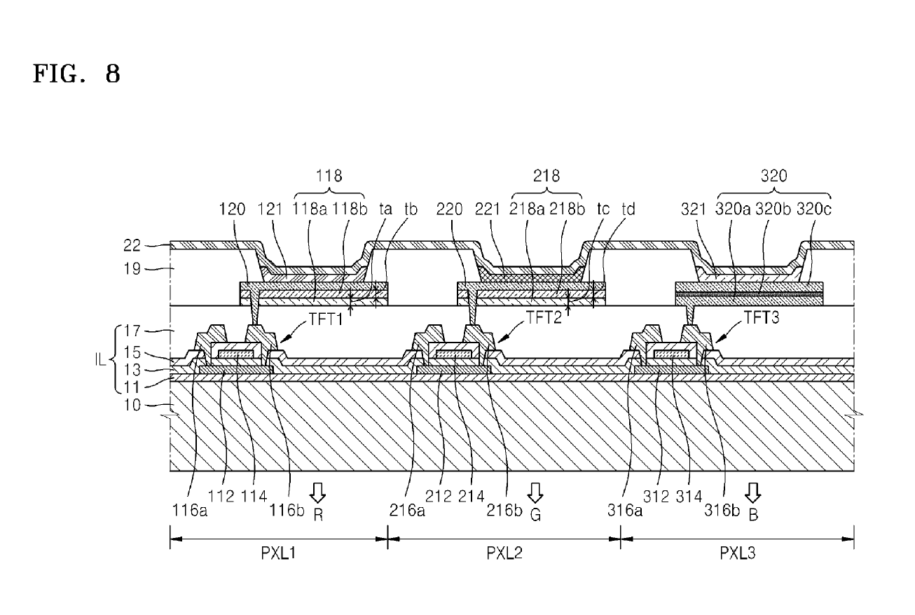

FIG. 8 is a schematic cross-sectional view illustrating an organic light-emitting display apparatus according to another exemplary embodiment of the present invention.

Referring to FIG. 8, an organic light-emitting display apparatus according to another embodiment has substantially the same configuration as the organic light-emitting display apparatus of FIG. 1 except for the configurations of the first dielectric reflective layer 118 and the second dielectric reflective layer 218.

In other words, the first dielectric reflective layer 118 is disposed in a region corresponding to the first pixel electrode 120, the second dielectric reflective layer 218 is disposed in a region corresponding to the second pixel electrode 220, and the first dielectric reflective layer 118 and the second dielectric reflective layer 218 are patterned.

The first dielectric reflective layer 118 may include the high refractive layer 118a and the low refractive layer 118b, and the second dielectric reflective layer 218 may include the high refractive layer 218a and the low refractive layer 218b.

The thicknesses ta, tb, tc, and td of the layers 118a, 118b, 218a, and 218b may be equal to or different from each other. Therefore, the wavelengths of lights emitted from the first subpixel region PXL1 and the second subpixel region PXL2 may be adjusted by changing the thicknesses ta, tb, tc, and tb.

Although FIG. 8 illustrates a configuration in which only one pair of high refractive layers 118a and 218a and low refractive layers 118b and 218b are disposed, embodiments of the present invention are not limited thereto. For example, a plurality of high refractive layers and low refractive layers may be disposed under the first pixel electrode 120 and the second pixel electrode 220, and the number of high refractive layers may be different from the number of low refractive layers.

FIG. 8 illustrates that the width of the first dielectric reflective layer 118 is equal to the width of the first pixel electrode 120 and the width of the second dielectric reflective layer 218 is equal to the width of the second pixel electrode 220. However, embodiments of the present invention are not limited thereto, and the widths of the first dielectric reflective layer 118 and the second dielectric reflective layer 218 may have any width as long as they are equal to or wider than the region to which light is emitted from the first intermediate layer 121 and the second intermediate layer 221.

The organic light-emitting display apparatuses according to the above embodiments may prevent a color shift depending on the side viewing angles, and may adjust the emitted red, green and blue light to the standard value s-RGB.

As described above, according to the one or more of the above embodiments of the present invention, the organic light-emitting display apparatuses may reduce a color shift depending on the side viewing angles.

It should be understood that the exemplary embodiments described herein should be considered in a descriptive sense only and not for purposes of limitation. Descriptions of features or aspects within each embodiment should typically be considered as available for other similar features or aspects in other embodiments.

While one or more embodiments of the present invention have been described with reference to the figures, it will be understood by those of ordinary skill in the art that various changes in form and details may be made therein without departing from the spirit and scope of the present invention as defined by the following claims.

What is claimed is:

1. An organic light-emitting display apparatus, comprising:
a substrate comprising a first subpixel region, a second subpixel region, and a third subpixel region;
a first pixel electrode, a second pixel electrode, and a third pixel electrode disposed respectively in the first subpixel region, the second subpixel region, and the third subpixel region;
a first intermediate layer, a second intermediate layer, and a third intermediate layer disposed respectively on the first pixel electrode, the second pixel electrode, and the third pixel electrode and comprising an organic emission layer;
an opposite electrode disposed on the first intermediate layer, the second intermediate layer, and the third intermediate layer; and
a dielectric reflective layer comprising at least one pair of a first refractive layer and a second refractive layer stacked alternately and disposed between the substrate and the first pixel electrode and between the substrate and the second pixel electrode,
wherein the first refractive layer has higher refractive index than the second refractive layer, and the third pixel electrode comprises a metal layer.

2. The organic light-emitting display apparatus of claim 1, wherein the first subpixel region, the second subpixel region, and the third subpixel region correspond respectively to a red subpixel region configured to emit red light, a green subpixel region configured to emit green light, and a blue subpixel region configured to emit blue light.

3. The organic light-emitting display apparatus of claim 1, wherein the third pixel electrode further comprises a first transparent conductive layer disposed under the metal layer and a second transparent conductive layer disposed on the metal layer.

4. The organic light-emitting display apparatus of claim 3, wherein the metal layer comprises silver (Ag) or an Ag alloy, and has a thickness of about 100 Å to about 200 Å.

5. The organic light-emitting display apparatus of claim 1, wherein the opposite electrode comprises a reflective metal layer.

6. The organic light-emitting display apparatus of claim 1, wherein the second refractive layer is disposed contacting the first pixel electrode and the second pixel electrode.

7. The organic light-emitting display apparatus of claim 1, wherein the dielectric reflective layer comprises a first dielectric reflective layer disposed corresponding to the first pixel electrode and a second dielectric reflective layer disposed corresponding to the second pixel electrode.

8. The organic light-emitting display apparatus of claim 7, wherein the first dielectric reflective layer and the second dielectric reflective layer have the same thickness.

9. The organic light-emitting display apparatus of claim 7, wherein the first refractive layer and the second refractive layer that comprise the first dielectric reflective layer and the second dielectric reflective layer have a thickness of about 760 Å to about 840 Å.

10. The organic light-emitting display apparatus of claim 1, wherein the first refractive layer comprises SiNₓ, and the second refractive layer comprises SiO₂.

11. An organic light-emitting display apparatus, comprising:
a substrate comprising a first subpixel region, a second subpixel region, and a third subpixel region;
a first pixel electrode, a second pixel electrode, and a third pixel electrode disposed respectively in the first subpixel region, the second subpixel region, and the third subpixel region;
a first intermediate layer, a second intermediate layer, and a third intermediate layer disposed respectively on the first pixel electrode, the second pixel electrode, and the third pixel electrode and comprising an organic emission layer;
an opposite electrode disposed on the first intermediate layer, the second intermediate layer, and the third intermediate layer;
a first dielectric reflective layer comprising at least one pair of a first refractive layer and a second refractive layer stacked alternately and disposed between the substrate and the first pixel electrode; and
a second dielectric reflective layer comprising at least one pair of a first refractive layer and a second refractive layer stacked alternately and disposed between the substrate and the second pixel electrode,
wherein the first refractive layer has higher refractive index than the second refractive layer, and the third pixel electrode comprises a metal layer.

12. The organic light-emitting display apparatus of claim 11, wherein the first dielectric reflective layer may have same width as the first intermediate layer and the second dielectric reflective layer may have same width as the second intermediate layer.

13. The organic light-emitting display apparatus of claim 11, wherein the third pixel electrode further comprises a first transparent conductive layer disposed under the metal layer and a second transparent conductive layer disposed on the metal layer to protect the metal layer.

14. The organic light-emitting display apparatus of claim 13, wherein the metal layer comprises silver (Ag) or an Ag alloy, and has a thickness of about 100 Å to about 200 Å.

15. The organic light-emitting display apparatus of claim 11, wherein the opposite electrode comprises a reflective metal layer.

16. The organic light-emitting display apparatus of claim 11, wherein the second refractive layer is disposed contacting the first pixel electrode and the second pixel electrode.

17. The organic light-emitting display apparatus of claim 11, wherein the first refractive layer and the second refractive layer that comprise the first dielectric reflective layer and the second dielectric reflective layer have a thickness of about 760 Å to about 840 Å

18. The organic light-emitting display apparatus of claim 11, wherein the first refractive layer comprises SiNₓ, and the second refractive layer comprises SiO₂.
